(19) United States
(12) Patent Application Publication
(10) Pub. No.: US 2026/0231493 A1
(43) Pub. Date: Aug. 6, 2026

(54) DIAMOND SEMICONDUCTOR DEVICE

(71) Applicant: NATIONAL INSTITUTE OF ADVANCED INDUSTRIAL SCIENCE AND TECHNOLOGY, Tokyo (JP)

(72) Inventors: Moriyoshi Haruyama, Ibaraki (JP); Hiromitsu Kato, Ibaraki (JP); Masahiko Ogura, Ibaraki (JP); Yukako Kato, Ibaraki (JP); Daisuke Takeuchi, Ibaraki (JP); Toshiharu Makino, Ibaraki (JP); Norikazu Mizuochi, Kyoto (JP); Hiroki Morishita, Kyoto (JP); Masanori Fujiwara, Kyoto (JP); Takayuki Iwasaki, Tokyo (JP)

(21) Appl. No.: 19/152,360

(22) PCT Filed: Jan. 25, 2024
(86) PCT No.: PCT/JP2024/002178

§ 371 Date: Dec. 5, 2025

(30) Foreign Application Priority Data
Feb. 1, 2023 (JP) 2023-013806

(51) Int. Cl. H10D 62/83; H10D 62/834

(52) U.S. Cl. CPC H10D 62/8303; H10D 62/834

(57) ABSTRACT

The present invention has an object to provide a diamond semiconductor device capable of EL emission through electrical excitation of NV⁻. A diamond semiconductor device according to the present invention includes, for example, a first diamond semiconductor layer (12) doped with phosphorus, a second diamond semiconductor layer (14) doped with an n-type impurity at a concentration higher than a phosphorus concentration in the first diamond semiconductor layer (12), a third diamond semiconductor layer (15) arranged so as to be spaced apart from the second diamond semiconductor layer (14) and doped with a p-type impurity at a concentration higher than the phosphorus concentration in the first diamond semiconductor layer (12), and an NV-center-containing diamond semiconductor layer (13), which has a crystal structure with NV centers formed therein, and is subjected to embedment in the first diamond semiconductor layer (12) so as to be opposed to a surface of the first diamond semiconductor layer (12) at a position sandwiched between the second diamond semiconductor layer (14) and the third diamond semiconductor layer (15), or other arrangement.

### TECHNICAL FIELD

The present invention relates to a diamond semiconductor device including diamond having a crystal structure with NV centers formed therein.

### BACKGROUND ART

The NV center (Nitrogen-Vacancy Center. Also called nitrogen-vacancy center, nitrogen vacancy center, NVC or the like) is a type of lattice defect in a diamond crystal structure, which is formed of a pair of a nitrogen atom that has entered so as to replace a carbon atom in position in a crystal lattice and a vacancy at a position adjacent to the nitrogen atom from which a carbon atom has been removed. An electron spin state of the NV center negatively charged (hereinafter referred to as “NV⁻”) due to an electron having been captured in the vacancy can be artificially manipulated by application of an external magnetic field, irradiation with microwaves or RF waves or the like, and a coherence time at room temperature is relatively long. Therefore, researches on the NV center are being actively conducted.

It has been reported that, for example: the NV centers are stabilized in an NV⁻ charge state by forming the NV center in phosphorus-doped n-type diamond (see Patent Literature 1); the coherence time can be prolonged by distributing phosphorus atoms in the diamond more widely than nitrogen atoms (see Patent Literature 2); and an NV axis of the NV center formed in the grown diamond is highly oriented by epitaxially growing a (111)-oriented diamond crystal (see Patent Literature 3).

In addition, as a quantum device using the NV centers, there has been developed a device for initializing and reading out the electron spin state in the NV⁻ by laser irradiation (see Non-Patent Literature 1). In such a device, it is possible to control and read out the electron spin state in the NV⁻ through optical detected magnetic resonance (ODMR) in which a resonant magnetic field is detected from an intensity of red fluorescence emitted from the NV⁻ through excitation by laser irradiation.

However, when the NV⁻ is excited by laser irradiation, an optical system formed of an objective lens, an excitation laser and the like is extremely large, and from the viewpoint of miniaturization and integration, electrical excitation of the NV⁻ without use of the optical system is required.

In this regard, attempts have been made to electrically excite the NV⁻ through use of a diamond semiconductor device having a lateral PIN diode structure which is formed by ion implanting phosphorus and boron into a selected region of a diamond substrate layer (i-layer) with the NV⁻ centers formed therein (see Non-Patent Literature 2) and a diamond semiconductor device having a vertical PIN diode structure in which a p-type diamond layer is arranged on one side of a low impurity-concentration diamond layer (i-layer) with the NV centers formed therein and an n-type diamond layer is arranged on the other side (see Non-Patent Literature 3).

However, in those proposals, while electrical excitation of the NV center in a neutral charge state (hereinafter referred to as “NV⁰”) has been enabled, electrical excitation of the NV⁻ required for quantum sensing has not been successfully achieved. This is considered to be because the NV⁰ has been dominant due to instability of the charge state in the NV⁻.

Accordingly, as a diamond semiconductor device in which the NV⁻ can be electrically excited and, consequently, electroluminescence (EL) for reading out a quantum state thereof can be emitted, none has existed to date.

### CITATION LIST

### Patent Literature

### [PTL 1]

JP 2019-152524 A

### [PTL 2]

JP 2021-134116 A

### [PTL 3]

JP 2022-191959 A

### Non-Patent Literature

### [NPL 1]

A. Gruber, et. al., Science 276, 2012 (1997).

### [NPL 2]

A. Lohrmann et. al., Appl. Phys. Lett. 99, 251106 (2011).

### [NPL 3]

N. Mizuochi et. al., Nat. Photonics 6, 299 (2012).

### SUMMARY OF INVENTION

### Technical Problem

The present invention has an object to solve the above-mentioned problems in the related art and to provide a diamond semiconductor device capable of EL emission through electrical excitation of the NV⁻.

### Solution to Problem

A solution to the above-mentioned problem is specifically as described below.

<1> A diamond semiconductor device, including: a first diamond semiconductor layer doped with phosphorus; a second diamond semiconductor layer arranged on a surface of the first diamond semiconductor layer, and doped with an n-type impurity at a concentration higher than a phosphorus concentration in the first diamond semiconductor layer so as to have an n-type conductivity; a third diamond semiconductor layer arranged on the surface of the first diamond semiconductor layer so as to be spaced apart from the second diamond semiconductor layer, and doped with a p-type impurity at a concentration higher than the phosphorus concentration in the first diamond semiconductor layer so as to have a p-type conductivity; and an NV-center-containing diamond semiconductor layer, which has a crystal structure in which NV centers are formed, and is: embedded in the first diamond semiconductor layer so as to be opposed to the surface of the first diamond semiconductor layer at a position sandwiched between the second diamond semiconductor layer and the third diamond semiconductor layer; arranged on the surface of the first diamond semiconductor layer at the position sandwiched between the second diamond semiconductor layer and the third diamond semiconductor layer; or arranged on a back surface of the first diamond semiconductor layer so as to be opposed to the surface of the first diamond semiconductor layer at the position sandwiched between the second diamond semiconductor layer and the third diamond semiconductor layer.

<2> The diamond semiconductor device according to Item <1>, wherein the diamond semiconductor device is configured such that an NV axis in at least one of the NV centers is perpendicular to a path of a current caused to flow in an in-plane direction of the first diamond semiconductor layer from the third diamond semiconductor layer toward the second diamond semiconductor layer.

<3> The diamond semiconductor device according to Item <1> or <2>, wherein the surface of the first diamond semiconductor layer has a (111) plane.

<4> The diamond semiconductor device according to any one of Items <1> to <3>, wherein the phosphorus concentration in the first diamond semiconductor layer is from 1×10¹⁵ cm⁻³ to 1×10¹⁸ cm⁻³.

<5> The diamond semiconductor device according to any one of Items <1> to <4>, wherein a thickness of the first diamond semiconductor layer is from 0.1 μm to 50 μm.

<6> The diamond semiconductor device according to any one of Items <1> to <5>, wherein a concentration of the NV centers in the NV-center-containing diamond semiconductor layer is 1×10¹⁹ cm⁻³ or less.

<7> The diamond semiconductor device according to any one of Items <1> to <6>, wherein a value of a product of the phosphorus concentration in the first diamond semiconductor layer and a thickness of the first diamond semiconductor layer is larger than a value of a product of a concentration of the NV centers in the NV-center-containing diamond semiconductor layer and a thickness of the NV-center-containing diamond semiconductor layer.

<8> The diamond semiconductor device according to any one of Items <1> to <7>, wherein a plurality of the NV-center-containing diamond semiconductor layers are arranged.

<9> The diamond semiconductor device according to any one of Items <1> to <8>, wherein the NV-center-containing diamond semiconductor layer is embedded in the first diamond semiconductor layer, and an embedding depth of the NV-center-containing diamond semiconductor layer, as viewed from the surface of the first diamond semiconductor layer, is 25 μm or less.

<10> The diamond semiconductor device according to any one of Items <1> to <9>, wherein a distance between the second diamond semiconductor layer and the third diamond semiconductor layer is from 0.1 μm to 50 μm.

<11> The diamond semiconductor device according to any one of Items <1> to <10>, wherein the second diamond semiconductor layer exhibits hopping conduction.

<12> The diamond semiconductor device according to any one of Items <1> to <11>, wherein the third diamond semiconductor layer exhibits hopping conduction.

<13> The diamond semiconductor device according to any one of Items <1> to <12>, further including an antenna circuit of microwaves or RF waves arranged such that an NV axis in at least one of the NV centers is perpendicular to an extending direction of an antenna.

### Advantageous Effects of Invention

According to the present invention, it is possible to solve the above-mentioned problems in the related-art technology and to provide the diamond semiconductor device capable of EL emission through electrical excitation of the NV⁻.

### BRIEF DESCRIPTION OF DRAWINGS

FIG. 1 is a cross-sectional view for illustrating an overview of a diamond semiconductor device according to a first embodiment of the present invention.

FIG. 2 is an explanatory diagram for illustrating a relationship between a current path and an NV axis.

FIG. 3 is an explanatory diagram for illustrating a top surface of a diamond semiconductor device including an antenna circuit.

FIG. 4 is a cross-sectional view for illustrating an overview of a diamond semiconductor device according to a second embodiment of the present invention.

FIG. 5 is a cross-sectional view for illustrating an overview of a diamond semiconductor device according to a third embodiment of the present invention.

FIG. 6 is a diagram for illustrating an optical microscope image obtained by photographing a top surface of a diamond semiconductor device according to Example 1.

FIG. 7 is a graph for showing current-voltage characteristics of the diamond semiconductor device according to Example 1.

FIG. 8(a) is a view for showing a two-dimensional mapping image of photoluminescence of the diamond semiconductor device according to Example 1.

FIG. 8(b) is a view for showing a two-dimensional mapping image of electroluminescence of the diamond semiconductor device according to Example 1.

FIG. 9 is a diagram for illustrating an optical microscope image obtained by photographing a top surface of a diamond semiconductor device according to Example 2.

FIG. 10 is a diagram for schematically illustrating a structure of the diamond semiconductor device according to Example 2.

FIG. 11 is a view for showing two-dimensional mapping images of light emission of an NV-center-containing diamond semiconductor layer observed from a first diamond semiconductor layer in the diamond semiconductor device according to Example 2.

FIG. 12 is a graph for showing light emission spectra of photoluminescence (PL) and electroluminescence (EL) in the diamond semiconductor device according to Example 2.

FIG. 13 is a view for showing a two-dimensional mapping image of electroluminescence of an NV-center-containing diamond semiconductor layer observed from a first diamond semiconductor layer in a diamond semiconductor device according to Example 3.

FIG. 14 is a graph for showing a relationship between a voltage applied to a lateral PIN diode structure and a light emission intensity of electroluminescence in the diamond semiconductor device according to Example 3.

FIG. 15 is a graph for showing results of SIMS analysis of a structure in which five NV-center-containing diamond semiconductor layers are embedded in a first diamond semiconductor layer in a diamond semiconductor device according to Example 4.

### DESCRIPTION OF EMBODIMENTS

### First Embodiment

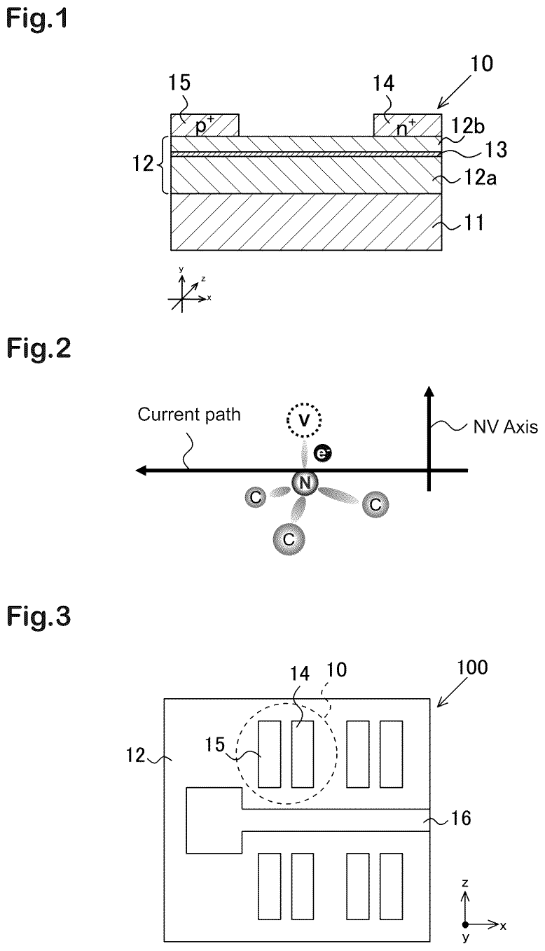

First, a diamond semiconductor device according to a first embodiment of the present invention is described with reference to FIG. 1.

As illustrated in FIG. 1, a diamond semiconductor device 10 according to the first embodiment includes a diamond substrate 11, a first diamond semiconductor layer 12 (12a and 12b), an NV-center-containing diamond semiconductor layer 13, a second diamond semiconductor layer 14 and a third diamond semiconductor layer 15.

The first diamond semiconductor layer 12 is formed of diamond doped with phosphorus. The phosphorus is doped at a lower concentration than impurity concentrations in the second diamond semiconductor layer 14 and the third diamond semiconductor layer 15, and the first diamond semiconductor layer 12 is positioned as an i (n⁻) layer in a publicly known lateral PIN diode structure.

As a specific phosphorus concentration in the first diamond semiconductor layer 12, there is no particular limitation as long as the phosphorus concentration is set as described above, but the phosphorus concentration is preferred to be from 1×10¹⁵ cm⁻³ to 1×10¹⁸ cm⁻³. With such a phosphorus concentration, NV centers formed in the NV-center-containing diamond semiconductor layer 13 are easily stabilized in the NV⁻ state.

A method of forming the first diamond semiconductor layer 12 is not particularly limited and includes a method of depositing and growing the layer on a publicly known diamond substrate by a chemical vapor deposition (CVD) method, one example of which is a microwave plasma chemical vapor deposition method using source gases that serve as a diamond source and a phosphorus source.

In this case, as the diamond substrate 11, a diamond substrate that is off-cut at a minute off-angle (from about 1° to about 8°) and has a (111) plane (main surface) is suitable. When the first diamond semiconductor layer 12 is deposited and grown on such a diamond substrate 11 by the CVD method, the first diamond semiconductor layer 12 having a (111) plane is obtained in conformity with surface properties of the diamond substrate 11. As the diamond substrate 11, a commercially available substrate (for example, an Ib substrate manufactured by TISNCM or Sumitomo Electric Industries, Ltd.) can be used.

Through use of the first diamond semiconductor layer 12 obtained in this manner, an NV axis of the NV center (axis extending from a nitrogen atom to a vacancy in the NV center) can be oriented in the [111] direction based on a crystal plane of the layer. That is, the NV axis is oriented in a direction perpendicular to the (111) plane of the diamond.

In this case, as illustrated in FIG. 2, there is established a state in which a path of a current caused to flow in an in-plane direction (x-direction indicated in FIG. 1) of the first diamond semiconductor layer 12 by being controlled by formation positions of the second diamond semiconductor layer 14 and the third diamond semiconductor layer 15 is perpendicular to the NV axis (y-direction indicated in FIG. 1) in the NV center, thereby enabling a plurality of the NV centers formed in the NV-center-containing diamond semiconductor layer 13 to be electrically excited under the same conditions and enabling quantum sensing to be performed under the same conditions by a simple optical system in which a photodetector is arranged so as to observe EL emitted from the NV centers from one direction.

Referring back to FIG. 1, the description is resumed.

The thickness of the first diamond semiconductor layer 12 is not particularly limited but is preferred to be from 0.1 μm to 50 μm. When the first diamond semiconductor layer 12 is too thin, it is difficult to form the NV-center-containing diamond semiconductor layer 13, and when the first diamond semiconductor layer 12 is too thick, a region that is not involved in current injection into the NV-center-containing diamond semiconductor layer 13 is liable to be generated.

The second diamond semiconductor layer 14 is arranged on the surface of the first diamond semiconductor layer and is formed of diamond doped with an n-type impurity at a concentration higher than the phosphorus concentration in the first diamond semiconductor layer 12 so as to have an n-type conductivity.

The n-type impurity is not particularly limited and can be appropriately selected from publicly known impurities, but when the n-type impurity is phosphorus, the second diamond semiconductor layer 14 can be formed from the same source gas as that of the first diamond semiconductor layer 12, thereby facilitating manufacture thereof.

In addition, the third diamond semiconductor layer 15 is arranged on the surface of the first diamond semiconductor layer 12 so as to be spaced apart from the second diamond semiconductor layer 14, and is formed of diamond doped with a p-type impurity at a concentration higher than the phosphorus concentration in the first diamond semiconductor layer 12 so as to have a p-type conductivity.

The p-type impurity is not particularly limited and can be appropriately selected from publicly known impurities, and examples thereof include boron.

The impurity concentrations in the second diamond semiconductor layer 14 and the third diamond semiconductor layer 15 are both higher than the phosphorus concentration in the first diamond semiconductor layer 12 and are positioned as the n⁺ layer and p⁺ layer in a publicly known lateral PIN diode structure.

The specific impurity concentrations in the second diamond semiconductor layer 14 and the third diamond semiconductor layer 15 are not particularly limited, but is preferred to be from about 1×10²⁰ cm⁻³ to about 1×10²¹ cm⁻³, and when the impurities are contained at such a high concentration, the second diamond semiconductor layer 14 and the third diamond semiconductor layer 15 that exhibit hopping conduction are provided.

The hopping conduction means that holes and electrons move through dense impurity levels, in contrast to band conduction, and a large current can be supplied to the first diamond semiconductor layer 12 that is in contact with the second diamond semiconductor layer 14 and the third diamond semiconductor layer 15.

The target to which the hopping conduction is imparted may be at least one of the second diamond semiconductor layer 14 and the third diamond semiconductor layer 15, but both thereof are particularly preferred to be the targets.

Metal electrodes (not shown) are formed on the respective surfaces of the second diamond semiconductor layer 14 and the third diamond semiconductor layer 15.

The metal electrodes are not particularly limited but are each preferred to be a single layer, or a laminate formed of at least one of gold, platinum, titanium, nickel, aluminum and an alloy thereof from the viewpoint of low contact resistance.

Further, a method of forming the metal electrodes is not particularly limited, and examples thereof include a publicly known vacuum evaporation method and a publicly known atomic layer deposition (ALD) method.

A distance (the shortest distance in the x-direction indicated in FIG. 1) between the second diamond semiconductor layer 14 and the third diamond semiconductor layer 15 is not particularly limited but is preferred to be from 0.1 μm to 50 μm. When the distance is too short, the current path in the first diamond semiconductor layer 12 is also short, and an effect of the current injection into the NV-center-containing diamond semiconductor layer 13, that is, an effect of electrically exciting the NV centers while stabilizing the NV centers in the NV⁻ state may be weakened. When the distance is too long, the size of the device is liable to be large, and a light-emitting area of the NV-center-containing diamond semiconductor layer 13 is also large, thereby sometimes causing an optical system for detecting the EL to be easily complicated.

A method of forming the second diamond semiconductor layer 14 and the third diamond semiconductor layer 15 is not particularly limited and includes a method of depositing and growing the layer by the CVD method, one example of which is the microwave plasma chemical vapor deposition method using source gases that serve as the diamond source and an impurity (phosphorus or boron) source.

In addition, those second diamond semiconductor layer 14 and third diamond semiconductor layer 15 are selectively formed at desired positions on the surface of the first diamond semiconductor layer, and such selective formation can be carried out by a selective processing method using publicly known masks.

An arrangement configuration of the second diamond semiconductor layer 14 (n⁺ layer) and the third diamond semiconductor layer 15 (p⁺ layer) relative to the first diamond semiconductor layer 12 (i (n⁻) layer) is positioned as the same configuration as that of a publicly known lateral PIN diode structure.

The NV-center-containing diamond semiconductor layer 13 has a crystal structure with the NV centers formed therein and is embedded in the first diamond semiconductor layer 12 so as to be opposed to the surface of the first diamond semiconductor layer 12 at a position sandwiched between the second diamond semiconductor layer 14 and the third diamond semiconductor layer 15.

That is, in the diamond semiconductor device 10, the NV-center-containing diamond semiconductor layer 13 is arranged at a position corresponding to the path of the current directed from the third diamond semiconductor layer 15 to the second diamond semiconductor layer 14 by being controlled by the formation positions of the second diamond semiconductor layer 14 and the third diamond semiconductor layer 15 based on the lateral PIN diode structure.

In the diamond semiconductor device 10, a current is stably injected into the NV-center-containing diamond semiconductor layer 13 based on such a configuration, and the NV centers are stabilized in an NV⁻ charge state by the electrical excitation.

As a method of forming the NV-center-containing diamond semiconductor layer 13, first, there is an ion implantation method of implanting N ions into the surface of the first diamond semiconductor layer 12 from the direction perpendicular to the surface. The N ions may be at least one of ¹⁴N ions, ¹⁵N ions and a mixture thereof.

During ion implantation, it is possible to change an implantation depth of the N ions within a range of from several nm to several tens of μm from the surface by changing energy for accelerating the N ions through setting of a voltage.

Further, in forming the NV-center-containing diamond semiconductor layer 13, it is preferred to anneal the layer in a temperature environment of from 800 degrees to 1,000 degrees for about 10 minutes to about 2 hours after the ion implantation.

In the case of using the first method, the NV-center-containing diamond semiconductor layer 13 can be directly formed in the first diamond semiconductor layer 12.

Secondly, there is a method of depositing and growing the layer by the CVD method, one example of which is a microwave plasma chemical vapor deposition method using a source gas that serves as the diamond source and a nitrogen gas.

In a case of using the second method, after the NV-center-containing diamond semiconductor layer 13 is deposited and formed on the first diamond semiconductor layer 12a, the first diamond semiconductor layer 12b is regrown on the NV-center-containing diamond semiconductor layer 13, to thereby be able to obtain the first diamond semiconductor layer 12 in which the NV-center-containing diamond semiconductor layer 13 is embedded.

That is, the source gas is switched between the gas (phosphine gas) that serves as the phosphorus source and the nitrogen gas, to thereby be able to continuously grow the first diamond semiconductor layer 12a, the NV-center-containing diamond semiconductor layer 13 and the first diamond semiconductor layer 12b in the stated order.

Due to a difference in the forming method, the NV-center-containing diamond semiconductor layer 13 can be a layer containing phosphorus in the first method, and the NV-center-containing diamond semiconductor layer 13 can be a layer not containing phosphorus in the second method. In consideration of this point, various matters of the first diamond semiconductor layer 12 (12a and 12b) and the NV-center-containing diamond semiconductor layer 13 are described.

A concentration of the NV centers in the NV-center-containing diamond semiconductor layer 13 is not particularly limited but is preferred to be 1×10¹⁹ cm⁻³ or less in any one of the methods. When the concentration is too high, injected electrons are dispersed due to the increased concentration of the NV centers, and hence the effect of the current injection into each individual NV center may be weakened.

It suffices that a lower limit of the concentration of the NV centers is a concentration required for forming the NV centers, which is about 1×10¹² cm⁻³.

The thickness of the NV-center-containing diamond semiconductor layer 13 is not particularly limited but is preferred to satisfy the following conditions.

That is, a value of a product of the phosphorus concentration in the first diamond semiconductor layer 12 and the thickness of the first diamond semiconductor layer 12 is preferred to be larger than a value of a product of the concentration of the NV centers in the NV-center-containing diamond semiconductor layer 13 and the thickness of the NV-center-containing diamond semiconductor layer 13. When this magnitude relationship is reversed, the total number of the NV centers exceeds the total amount of phosphorus, and an effect of stabilizing the charge state for the NV centers may be weakened.

As the thickness of the first diamond semiconductor layer 12 under the above-mentioned conditions, the thickness of the first diamond semiconductor layer 12 itself is employed in the case of using the first method, and the total thickness of the first diamond semiconductor layer 12a and the first diamond semiconductor layer 12b (the thickness obtained by subtracting the thickness of the NV-center-containing diamond semiconductor layer 13 from the thickness of the first diamond semiconductor layer 12) is employed in the case of using the second method.

An embedding depth (the shortest distance between the surface and the NV-center-containing diamond semiconductor layer 13 in the y-direction indicated in FIG. 1) of the NV-center-containing diamond semiconductor layer 13 embedded in the first diamond semiconductor layer 12, as viewed from the surface of the first diamond semiconductor layer 12, is not particularly limited, but is preferred to be 25 μm or less in any one of the forming methods. When the embedding depth is too deep, the position may deviate from the current path, and electroluminescence emission from the NV centers may be weakened. The embedding depth in the shallowest case is about 1 nm in consideration of a film formation limit of the first diamond semiconductor layer 12b (a single layer).

Herein, the embedding means that, as illustrated in FIG. 1, the surface and a back surface of the NV-center-containing diamond semiconductor layer 13 are covered with the first diamond semiconductor layer 12 (12a and 12b), and also indicates that the entire surface of the NV-center-containing diamond semiconductor layer 13 including side surfaces thereof is covered with the first diamond semiconductor layer 12.

That is, as the NV-center-containing diamond semiconductor layer 13, any layer arranged so as to be opposed to the surface of the first diamond semiconductor layer 12 at the position sandwiched between the second diamond semiconductor layer 14 and the third diamond semiconductor layer 15 can receive the effect of the current injection corresponding to the current path between the second diamond semiconductor layer 14 and the third diamond semiconductor layer 15. For example, an extension length of the NV-center-containing diamond semiconductor layer 13 may be restricted to a length corresponding to a portion opposed to the surface of the first diamond semiconductor layer 12 at the position sandwiched between the second diamond semiconductor layer 14 and the third diamond semiconductor layer 15 (with the left and right end portions being cut off in FIG. 1) such that the entire NV-center-containing diamond semiconductor layer 13 including the side surfaces thereof are covered with the first diamond semiconductor layer 12. Examples of such a selective method of forming the NV-center-containing diamond semiconductor layer 13 relative to the first diamond semiconductor layer 12 include a selective processing method using a publicly known mask.

Further, the NV-center-containing diamond semiconductor layer 13 is not always required to be embedded in the first diamond semiconductor layer 12, and there is also provided a modification example in which the first diamond semiconductor layer 12a is not formed in the diamond semiconductor device 10 illustrated in FIG. 1.

That is, there is also provided a modification example in which the NV-center-containing diamond semiconductor layer 13 is arranged on a back surface of the first diamond semiconductor layer 12b so as to be opposed to the surface of the first diamond semiconductor layer 12b at the position sandwiched between the second diamond semiconductor layer 14 and the third diamond semiconductor layer 15.

An arrangement structure of the NV-center-containing diamond semiconductor layer 13 in such a modification example can be obtained by, for example, depositing and forming the NV-center-containing diamond semiconductor layer 13 on the diamond substrate 11 by the second method (CVD method) and forming the first diamond semiconductor layer 12b on the NV-center-containing diamond semiconductor layer 13.

In the diamond semiconductor device 10 according to the first embodiment which is configured as described above, the NV centers in the NV-center-containing diamond semiconductor layer 13 can be electrically excited while being stabilized in the NV⁻ state through application of a forward bias voltage, thereby enabling the NV centers to emit the EL of the NV⁻ required for quantum sensing.

The detected EL of the NV⁻ provides information on an electron spin state (up-spin or down-spin) in the NV centers. A method of acquiring information on the electron spin state from the EL of the NV⁻ is not particularly limited, and examples thereof include a publicly known optical detected magnetic resonance (ODMR) method.

Further, a method of controlling the electron spin state for the NV centers is not particularly limited and can be appropriately selected from publicly known methods, and examples thereof include a method of irradiating the NV centers with microwaves or radio frequency (RF) waves to induce Rabi oscillations in electrons captured by the NV centers.

FIG. 3 is an illustration of a device configuration example in a case of using microwaves or RF waves.

As illustrated in FIG. 3, in a diamond semiconductor device 100, four element structures each formed of the diamond semiconductor device 10 (see FIG. 1) are integrated.

In this case, when the NV axis in the NV center is oriented in the direction (y-direction of FIG. 1 and FIG. 3) perpendicular to the (111) plane of the diamond, an antenna circuit 16 is arranged such that the NV axis is perpendicular to an extending direction (x-direction of FIG. 3) of the antenna of the antenna circuit 16, thereby enabling electron spin control under the same conditions for all the four element structures. That is, it is possible to densely arrange the element structures of the diamond semiconductor device 10 with the antenna of the antenna circuit 16 located at the center, thereby achieving high integration.

Further, the diamond semiconductor device 10 according to the first embodiment (see FIG. 1) can be operated in the same manner as a publicly known photodetector due to having a PIN diode structure, and generates a photocurrent in response to irradiation with light carrying electron spin information with a reverse bias voltage applied, the photocurrent having a magnitude corresponding to the electron spin state. That is, the diamond semiconductor device 10 according to the first embodiment can be not only used as a light source that emits light carrying electron spin information but also used as a photodetector for reading out the electron spin state from light carrying electron spin information.

### Second Embodiment

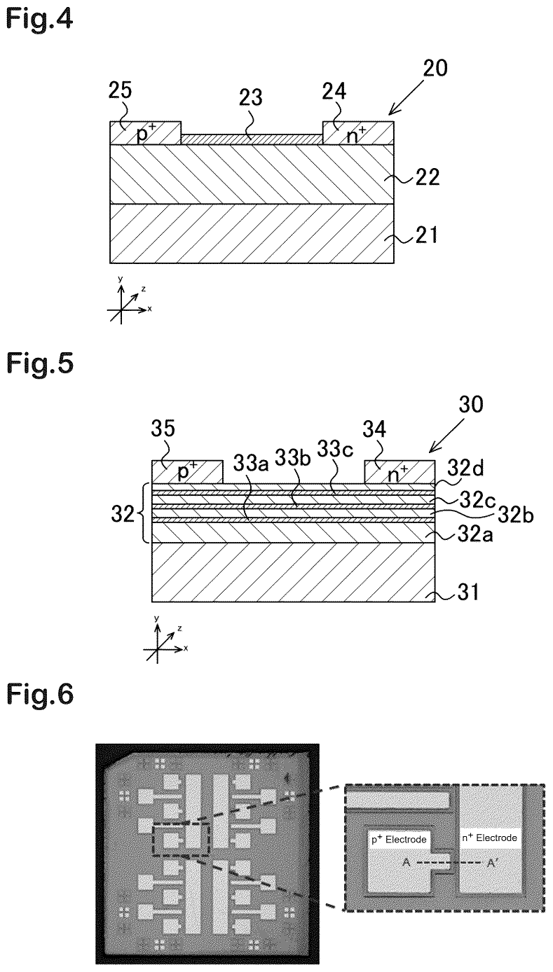

Next, a diamond semiconductor device according to a second embodiment of the present invention is described with reference to FIG. 4.

As illustrated in FIG. 4, a diamond semiconductor device 20 according to the second embodiment includes a diamond substrate 21, a first diamond semiconductor layer 22, an NV-center-containing diamond semiconductor layer 23, a second diamond semiconductor layer 24 and a third diamond semiconductor layer 25.

The diamond substrate 21, the first diamond semiconductor layer 22, the second diamond semiconductor layer 24 and the third diamond semiconductor layer 25 are configured in the same manner as the diamond substrate 11, the first diamond semiconductor layer 12, the second diamond semiconductor layer 14 and the third diamond semiconductor layer 15 in the diamond semiconductor device 10 according to the first embodiment.

In the diamond semiconductor device 20 according to the second embodiment, unlike in the diamond semiconductor device 10 according to the first embodiment, the NV-center-containing diamond semiconductor layer 23 is arranged on a surface of the first diamond semiconductor layer 22 sandwiched between the second diamond semiconductor layer 24 and the third diamond semiconductor layer 25.

As a method of forming the NV-center-containing diamond semiconductor layer 23, the second method for the first diamond semiconductor layer 12a, which has been described above in the diamond semiconductor device 10, may be used.

Further, the NV-center-containing diamond semiconductor layer 23 can be configured in the same manner as the NV-center-containing diamond semiconductor layer 13 in the diamond semiconductor device 10, except for the description relating to a formation position thereof.

In the diamond semiconductor device 20 according to the second embodiment which is configured in such a manner, the NV-center-containing diamond semiconductor layer 23 is also arranged on a path of a current directed from the third diamond semiconductor layer 25 to the second diamond semiconductor layer 24 by being controlled by formation positions of the second diamond semiconductor layer 24 and the third diamond semiconductor layer 25, thereby enabling the NV centers to be electrically excited while being stabilized in the NV⁻ state and enabling the NV centers to emit the EL of the NV⁻.

### Third Embodiment

Next, a diamond semiconductor device according to a third embodiment of the present invention is described with reference to FIG. 5.

As illustrated in FIG. 5, a diamond semiconductor device 30 according to the third embodiment includes a diamond substrate 31, a first diamond semiconductor layer 32 (32a, 32b, 32c and 32d), NV-center-containing diamond semiconductor layers 33a, 33b and 33c, a second diamond semiconductor layer 34 and a third diamond semiconductor layer 35.

The diamond substrate 31, the first diamond semiconductor layer 32, the second diamond semiconductor layer 34 and the third diamond semiconductor layer 35 are configured in the same manner as the diamond substrate 11, the first diamond semiconductor layer 12, the second diamond semiconductor layer 14 and the third diamond semiconductor layer 15 in the diamond semiconductor device 10 according to the first embodiment.

In the diamond semiconductor device 30 according to the third embodiment, unlike in the diamond semiconductor device 10 according to the first embodiment, three NV-center-containing diamond semiconductor layers 33a, 33b and 33c are embedded in the first diamond semiconductor layer 32.

As a method of forming the NV-center-containing diamond semiconductor layers 33a, 33b and 33c, the second method (the method in which the diamond layers are continuously grown), which has been described above in the diamond semiconductor device 10, may be used.

Each of the NV-center-containing diamond semiconductor layers 33a, 33b and 33c can be configured in the same manner as the NV-center-containing diamond semiconductor layer 13 in the diamond semiconductor device 10.

However, in regard to the condition in the diamond semiconductor device 10 according to the first embodiment that the value of the product of the phosphorus concentration in the first diamond semiconductor layer and the thickness of the first diamond semiconductor layer is larger than the value of the product of the concentration of the NV centers in the NV-center-containing diamond semiconductor layer and the thickness of the NV-center-containing diamond semiconductor layer, an average concentration in the NV-center-containing diamond semiconductor layers 33a, 33b and 33c is employed as the concentration of the NV centers, and a total thickness of the NV-center-containing diamond semiconductor layers 33a, 33b and 33c is employed as the thickness of the NV-center-containing diamond semiconductor layer. Further, an average concentration in the first diamond semiconductor layers 32a, 32b, 32c and 32d is employed as the phosphorus concentration, and a total thickness of the first diamond semiconductor layers 32a, 32b, 32c and 32d is employed as the thickness of the first diamond semiconductor layer.

In addition, in regard to the condition regarding the embedding depth position of the NV-center-containing diamond semiconductor layer embedded in the first diamond semiconductor layer, as viewed from the surface of the first diamond semiconductor layer, when the NV-center-containing diamond semiconductor layer 33a present at the deepest position satisfies the condition, the NV-center-containing diamond semiconductor layers 33b and 33c also satisfy the condition.

In the diamond semiconductor device 30 according to the third embodiment, the NV-center-containing diamond semiconductor layer 33c arranged on the outermost surface side is configured as a layer embedded in the first diamond semiconductor layer 32, but there is also provided a modification example in which the NV-center-containing diamond semiconductor layer 33c is arranged on the surface of the first diamond semiconductor layer 32 in the same manner as the NV-center-containing diamond semiconductor layer 23 in the diamond semiconductor device 20 according to the second embodiment.

There is also provided a modification example of a diamond semiconductor device configured in the same manner as the diamond semiconductor device 30 according to the third embodiment except that the NV-center-containing diamond semiconductor layer 33a is directly arranged on the diamond substrate 31 without forming the first diamond semiconductor layer 32a constituting the lowermost layer.

Further, the number of the NV-center-containing diamond semiconductor layers is not particularly limited and can be freely changed.

In the diamond semiconductor device 30 according to the third embodiment which is configured in such a manner, the NV-center-containing diamond semiconductor layers 33a, 33b and 33c are also arranged on a path of a current directed from the third diamond semiconductor layer 35 to the second diamond semiconductor layer 34 by being controlled by formation positions of the second diamond semiconductor layer 34 and the third diamond semiconductor layer 35, thereby enabling the NV centers to be electrically excited while being stabilized in the NV⁻ state and enabling the NV centers to emit the EL of the NV⁻.

### EXAMPLES

### Example 1

A diamond semiconductor device according to Example 1 was manufactured in accordance with the configuration illustrated in FIG. 1.

Specific description thereof is given below.

<First Diamond Semiconductor Layer: i (n⁻) Layer>

First, a diamond substrate (manufactured by TISNCM; type Ib substrate), which was off-cut at an off-cut angle exhibiting slight inclination and had a (111) plane as its main surface, was prepared.

When the off-angle and off-direction of the diamond substrate were measured by an X-ray diffraction method, the off-angle was 2.5° and the off-direction was <−1-12>.

Subsequently, an i (n⁻)-type diamond semiconductor layer serving as a first diamond semiconductor layer was formed on the diamond substrate by a plasma chemical vapor deposition apparatus (manufactured by Cornes Technologies Limited; AX5250) using microwaves.

Specifically, a hydrogen gas, a methane gas and a phosphine gas that imparts the n-type conductivity were used as source gases to be respectively introduced into the plasma chemical vapor deposition apparatus with a flow rate of 996 sccm for the hydrogen gas, a flow rate of 4 sccm for the methane gas and a flow rate of 2 sccm for the hydrogen-diluted phosphine gas (phosphine concentration: 0.1% by volume), and the first diamond semiconductor layer was formed on the diamond substrate under deposition conditions for the plasma chemical vapor deposition apparatus of a plasma input power of 3,600 W, a pressure of 150 Torr and a deposition time of 4 hours.

The phosphorus concentration in the first diamond semiconductor layer measured by a secondary-ion mass spectrometry (SIMS) analyzer (manufactured by CAMECA SAS; IMS-0f) was 6×10¹⁶ cm⁻³. Other impurities, hydrogen and nitrogen were below a background level of the SIMS analysis, and boron was below a detection limit.

Further, the thickness of the first diamond semiconductor layer, as measured by the SIMS analyzer, was 10 μm.

Further, the surface of the first diamond semiconductor layer was formed in a shape in which terrace surfaces and step surfaces were alternately formed in one direction in conformity with a surface shape of the diamond substrate. Further, the terrace surface had a (111) plane in conformity with the surface shape of the diamond substrate.

<Second Diamond Semiconductor Layer: n⁺ Layer>

Next, a second diamond semiconductor layer having an n-type (n⁺-type) conductivity was formed on the first diamond semiconductor layer as follows.

First, the surface of the first diamond semiconductor layer was cleaned by a boiling treatment using a mixed solution of sulfuric acid and nitric acid.

Subsequently, a resist material was applied onto the first diamond semiconductor layer by spin coating, and then a resist pattern was formed on the first diamond semiconductor layer by performing an exposure treatment using a mask followed by a development treatment, the resist pattern being formed so as to cover only a region for forming the second diamond semiconductor layer. After that, a material (Ti) of a metal mask was deposited to a thickness of 500 nm on the first diamond semiconductor layer. After that, the resist pattern was removed by lift-off, to thereby form the metal mask on a region other than the region for forming the second diamond semiconductor layer.

Subsequently, the second diamond semiconductor layer was selectively grown by the plasma chemical vapor deposition apparatus on the region on the first diamond semiconductor layer on which the metal mask was not formed.

Specifically, the hydrogen gas, the methane gas and the phosphine gas that imparts the n-type conductivity were used as source gases to be respectively introduced into the plasma chemical vapor deposition apparatus with a flow rate of 400 sccm for the hydrogen gas, a flow rate of 0.2 sccm for the methane gas and a flow rate of 0.2 sccm for the hydrogen-diluted phosphine gas (phosphine concentration: 5% by volume), and the above-mentioned deposition and formation were performed under deposition conditions for the plasma chemical vapor deposition apparatus of a plasma input power of 750 W, a pressure of 75 Torr and a deposition time of 1 hour, after which the metal mask was removed by acid cleaning.

The phosphorus concentration in the second diamond semiconductor layer, as measured by the SIMS analyzer, was 2×10²⁰ cm⁻³.

Further, the thickness of the second diamond semiconductor layer, as measured by the SIMS analyzer, was 0.2 μm.

<Third Diamond Semiconductor Layer: p⁺ Layer>

Next, a third diamond semiconductor layer having a p-type (p⁺-type) conductivity was formed on the first diamond semiconductor layer as follows.

First, the surface of the first diamond semiconductor layer was cleaned by a boiling treatment using a mixed solution of sulfuric acid and nitric acid.

Subsequently, a resist material was applied onto each of the surfaces of the first diamond semiconductor layer and the second diamond semiconductor layer by spin coating, and then a resist pattern configured to cover only a region for forming the third diamond semiconductor layer was formed by performing an exposure treatment using a mask followed by a development treatment. After that, a material (Ti) of a metal mask was deposited to a thickness of 500 nm on the first diamond semiconductor layer and the second diamond semiconductor layer. After that, the resist pattern was removed by lift-off, to thereby form the metal mask on a region other than the region for forming the third diamond semiconductor layer.

Subsequently, the third diamond semiconductor layer was selectively grown by the plasma chemical vapor deposition apparatus on the region on the first diamond semiconductor layer on which the metal mask was not formed.

Specifically, the hydrogen gas, the methane gas and trimethylboron that imparts the p-type conductivity were used as source gases to be respectively introduced into the plasma chemical vapor deposition apparatus with a flow rate of 399 sccm for the hydrogen gas, a flow rate of 0.8 sccm for the methane gas and a flow rate of 0.8 sccm for the hydrogen-diluted trimethylboron gas (trimethylboron concentration: 1% by volume), and the above-mentioned deposition and formation were performed under deposition conditions for the plasma chemical vapor deposition apparatus of a plasma input power of 1,200 W, a pressure of 50 Torr and a deposition time of 0.16 hour, after which the metal mask was removed by acid cleaning.

The boron concentration in the third diamond semiconductor layer, as measured by the SIMS analyzer, was 8×10²⁰ cm⁻³.

Further, the thickness of the third diamond semiconductor layer, as measured by the SIMS analyzer, was 0.05 μm.

In this Example, the second diamond semiconductor layer is formed prior to the third diamond semiconductor layer, but the order of formation of those layers may be freely set.

### <Formation of the NV-Center-Containing Diamond Semiconductor Layer: Ion Implantation Method>

Next, an NV-center-containing diamond semiconductor layer was formed in the first diamond semiconductor layer by the ion implantation method.

First, the surface of the first diamond semiconductor layer was cleaned by a boiling treatment using a mixed solution of sulfuric acid and nitric acid.

Subsequently, ¹⁴N ions were accelerated at 350 keV, and implanted into the surface of the first diamond semiconductor layer heated to 600° C. under a condition that a dose amount was 5×10⁸ cm⁻².

After that, a high-temperature heat treatment was performed in an Ar atmosphere at 850° C. for 30 minutes, to thereby form the NV-center-containing diamond semiconductor layer containing NV centers in the first diamond semiconductor layer.

From a stopping and range ion in matter (SRIM) simulation, the depth position of the NV-center-containing diamond semiconductor layer formed in the first diamond semiconductor layer, as viewed from the surface of the first diamond semiconductor layer, was 340 nm.

### <Electrode>

Next, an electrode was formed on each of the surfaces of the second diamond semiconductor layer and the third diamond semiconductor layer as follows.

First, each of the surfaces of the second diamond semiconductor layer and the third diamond semiconductor layer was cleaned by a boiling treatment using a mixed solution of sulfuric acid and nitric acid.

Subsequently, a resist material was applied onto the surfaces of the first diamond semiconductor layer, the second diamond semiconductor layer and the third diamond semiconductor layer by spin coating, and then a resist pattern configured not to cover each of the surfaces of the second diamond semiconductor layer and the third diamond semiconductor layer was formed by performing an exposure treatment using a mask followed by a development treatment. After that, a stacked electrode of Au (100 nm)/Pt (30 nm)/Ti (30 nm) was deposited through use of a vacuum evaporation apparatus (manufactured by Eiko Engineering Co., Ltd.; electron beam evaporator), and after that, the resist pattern was removed by lift-off, to thereby form the electrode on each of the surfaces of the second diamond semiconductor layer and the third diamond semiconductor layer.

Through the above-mentioned steps, the diamond semiconductor device according to Example 1 was manufactured.

FIG. 6 shows an optical microscope image obtained by photographing a top surface of the diamond semiconductor device according to Example 1. A cross-sectional structure of a region taken along the line A-A′ in the partially enlarged portion of FIG. 6 corresponds to the cross-sectional structure of FIG. 1.

The diamond semiconductor device according to Example 1 is manufactured in accordance with the diamond semiconductor device illustrated in FIG. 1, but at positions beneath the second diamond semiconductor layer and the third diamond semiconductor layer, implantation positions of the ¹⁴N ions implanted from above the surfaces of the second diamond semiconductor layer and the third diamond semiconductor layer are located, with respect to a position in the first diamond semiconductor layer, on the surface side thereof by amounts corresponding to thicknesses of the second diamond semiconductor layer and the third diamond semiconductor layer. The ¹⁴N ions implanted into the positions beneath the second diamond semiconductor layer and the third diamond semiconductor layer do not contribute to an operation of the diamond semiconductor device according to Example 1.

### <Semiconductor Properties>

In the diamond semiconductor device according to Example 1, semiconductor properties of each of the first diamond semiconductor layer (i (n⁻) layer), the second diamond semiconductor layer (n⁺ layer) and the third diamond semiconductor layer (p⁺ layer) were measured by a Hall effect measuring apparatus (manufactured by Toyo Corporation; ResiTest 8300). The measurements were carried out on the first diamond semiconductor layer (i (n⁻) layer), the second diamond semiconductor layer (n⁺ layer) and the third diamond semiconductor layer (p⁺ layer), each in a single-layer state.

As a result, in the first diamond semiconductor layer doped with phosphorus, a Hall electromotive force having a negative value was observed, thereby being able to confirm n-type semiconductor properties indicating that carriers thereof were electrons.

Further, also in the second diamond semiconductor layer doped with phosphorus at a high concentration, a Hall electromotive force having a negative value was observed, thereby being able to confirm n-type semiconductor properties indicating that carriers thereof were electrons and that hopping conduction was exhibited.

Further, in the third diamond semiconductor layer doped with boron at a high concentration, a Hall electromotive force having a positive value was observed, thereby being able to confirm p-type semiconductor properties indicating that carriers thereof were holes and that hopping conduction was exhibited.

### <Current-Voltage Characteristics>

Current-voltage characteristics of the diamond semiconductor device according to Example 1 were measured through use of a semiconductor parameter analyzer (manufactured by Keithley Instruments, LLC; 4200A). The measurement was performed by measuring a value of a current flowing when a voltage was swept in a range of from −50 V to +50 V.

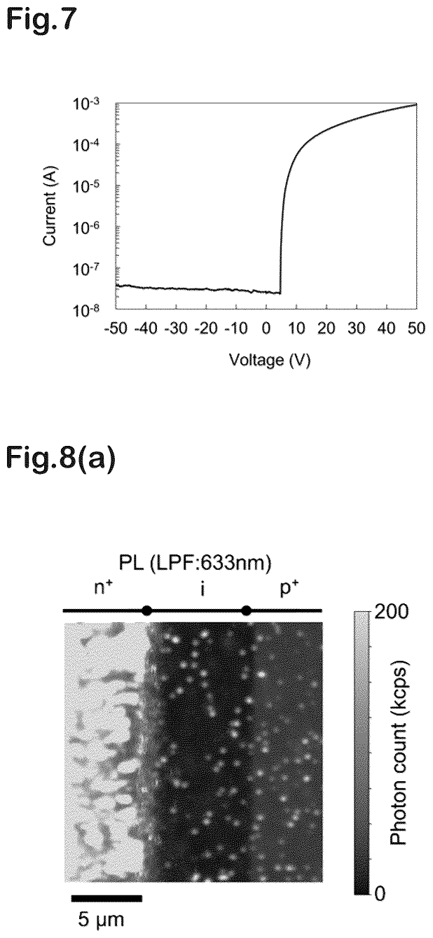

The current-voltage characteristics of the diamond semiconductor device according to Example 1 are shown in FIG. 7.

As shown in FIG. 7, the diamond semiconductor device according to Example 1 was confirmed to exhibit a clear rectifying characteristic. That is, it was confirmed that a lateral PIN diode was properly formed.

Specifically, when a forward voltage of 5 V or more is applied, the diode is turned on, and when a voltage less than that is applied, the diode is turned off.

Further, in an ON state, electroluminescence light emission was observed.

### <Light Emission Characteristics>

In order to clarify light emission characteristics of the diamond semiconductor device according to Example 1, analysis using a confocal fluorescence microscope or the like was performed as follows.

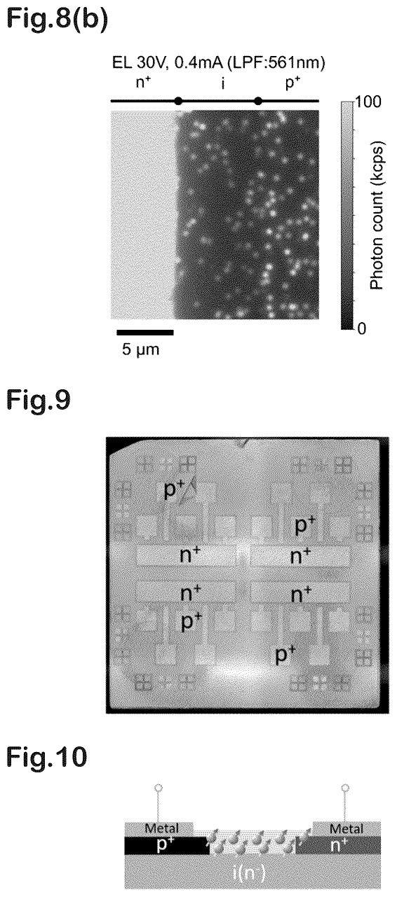

First, FIG. 8(a) and FIG. 8(b) show two-dimensional mapping images of light emission of the NV-center-containing diamond semiconductor layer observed from the first diamond semiconductor layer (i (n⁻) layer) near the center of the lateral PIN diode structure. FIG. 8(a) is a view for showing a photoluminescence image, and FIG. 8(b) is a view for showing an electroluminescence image. In the confocal microscope, focus is formed through a 30 μm pinhole, and hence a light-emitting point is detected with high spatial resolution.

In this case, the photoluminescence image represents a mapping of intensities of PL light emitted from a sample when the sample is irradiated with laser light having a wavelength of 532 nm, while the electroluminescence image represents a mapping of intensities of EL light emission at a time of current injection obtained by applying a voltage of 30 V to the lateral PIN diode.

As shown in FIG. 8(a) and FIG. 8(b), the light emission from the first diamond semiconductor layer (i (n⁻) layer) is observed as bright spots (light emission from single one of the NV centers), and those bright spots are observed at the same positions in both the photoluminescence image and the electroluminescence image.

Those observations confirm that electrical excitation and EL emission occur in each single one of the NV centers.

Further, when antibunching measurements and spectral evaluations of the light emission were performed in accordance with References 1 and 2 below, it was confirmed that those bright spots were each single-photon emission from the negatively charged NV⁻.

That is, single-photon emission from the NV⁻ was successfully obtained for the first time by the electrical excitation through use of the diamond semiconductor device according to Example 1 without relying on a related-art method of obtaining single-photon emission from the NV⁻ by optical excitation.

Reference 1: A. Beveratos et al. Eur. Phys. J. D 18, 191 (2002).
Reference 2: N. Mizuochi et al., Nat. Photonics 6, 299 (2012).

### Example 2

A diamond semiconductor device according to Example 2 was manufactured in accordance with the configuration illustrated in FIG. 4. In Example 2, the NV-center-containing diamond semiconductor layer is formed by changing the method of forming the NV-center-containing diamond semiconductor layer from the ion implantation method in Example 1 to the CVD method.

Specific description thereof is given below.

<First Diamond Semiconductor Layer: i (n⁻) Layer>

First, a diamond substrate (manufactured by Sumitomo Electric Industries, Ltd.; type Ib substrate), which was off-cut at an off-cut angle exhibiting slight inclination and had a (111) plane as its main surface, was prepared.

When the off-angle and off-direction of the diamond substrate were measured by the X-ray diffraction method, the off-angle was 2.7° and the off-direction was a direction displaced by +10° from <−1-12>.

Subsequently, the i (n⁻)-type diamond semiconductor layer was formed on the diamond substrate as the first diamond semiconductor layer in the same manner as in Example 1 except that the flow rate of the hydrogen-diluted phosphine gas was changed from 2 sccm to 1 sccm and the film formation time was changed from 4 hours to 5 hours.

The phosphorus concentration in the first diamond semiconductor layer measured by the SIMS analyzer was 3×10¹⁶ cm⁻³. Other impurities, hydrogen and nitrogen were below the background level of the SIMS analysis, and boron was below the detection limit.

Further, the thickness of the first diamond semiconductor layer, as measured by the SIMS analyzer, was 15 μm.

Further, the surface of the first diamond semiconductor layer was formed in a shape in which terrace surfaces and step surfaces were alternately formed in one direction in conformity with a surface shape of the diamond substrate. Further, the terrace surface had a (111) plane in conformity with the surface shape of the diamond substrate.

<Second Diamond Semiconductor Layer: n⁺ Layer>

Next, the second diamond semiconductor layer was selectively grown on the first diamond semiconductor layer through use of the metal mask in the same manner as in Example 1 except that the pressure condition for film formation was changed from 75 Torr to 25 Torr.

The phosphorus concentration in the second diamond semiconductor layer, as measured by the SIMS analyzer, was 2×10²⁰ cm⁻³.

Further, the thickness of the second diamond semiconductor layer, as measured by the SIMS analyzer, was 0.15 μm.

<Third Diamond Semiconductor Layer: p⁺ Layer>

Next, the third diamond semiconductor layer was selectively grown on the first diamond semiconductor layer through use of the metal mask in the same manner as in Example 1. The boron concentration and thickness in the third diamond semiconductor layer, as measured by the SIMS analyzer, were the same as in Example 1.

### <Formation of NV-Center-Containing Diamond Semiconductor Layer: CVD Method>

Next, the NV-center-containing diamond semiconductor layer was formed in the first diamond semiconductor layer by the CVD method as follows.

First, a resist material was applied onto the first diamond semiconductor layer by spin coating, and then a resist pattern configured to cover only the surface of the first diamond semiconductor layer was formed by performing an exposure treatment using a mask followed by a development treatment. After that, a material (Ti) of a metal mask was deposited on the resist pattern. After that, the resist pattern was removed by lift-off, to thereby form the metal mask only on each of the surfaces of the second diamond semiconductor layer and the third diamond semiconductor layer.

Subsequently, a nitrogen-doped diamond layer containing the NV centers was formed as the NV-center-containing diamond semiconductor layer by the plasma chemical vapor deposition apparatus on the region on the first diamond semiconductor layer on which the metal mask was not formed.

Specifically, the hydrogen gas, the methane gas and the nitrogen gas for forming the NV centers were used as source gases to be respectively introduced into the plasma chemical vapor deposition apparatus with a flow rate of 999 sccm for the hydrogen gas, a flow rate of 1 sccm for the methane gas and a flow rate of 0.05 sccm for the nitrogen gas, and the NV-center-containing diamond semiconductor layer was formed on the first diamond semiconductor layer under deposition conditions for the plasma chemical vapor deposition apparatus of a plasma input power of 3,500 W, a pressure of 120 Torr and a deposition time of 30 minutes. After that, the metal mask was removed by acid cleaning.

The nitrogen concentration in the NV-center-containing diamond semiconductor layer, as measured by the SIMS analyzer, was 1×10¹⁸ cm⁻³.

Further, the thickness of the NV-center-containing diamond semiconductor layer, as measured by the SIMS analyzer, was 1 μm.

### <Electrode>

Next, in the same manner as in Example 1, the electrode (stacked electrode of Au (100 nm)/Pt (30 nm)/Ti (30 nm)) was formed on each of the surfaces of the second diamond semiconductor layer and the third diamond semiconductor layer.

Through the above-mentioned steps, the diamond semiconductor device according to Example 2 was manufactured.

FIG. 9 shows an optical microscope image obtained by photographing the top surface of the diamond semiconductor device according to Example 2.

The diamond semiconductor device according to Example 2 has a structure in which, compared to the diamond semiconductor device 20 illustrated in FIG. 4, the thickness of the NV-center-containing diamond semiconductor layer is larger than the thicknesses of the second diamond semiconductor layer and the third diamond semiconductor layer with each side end of the NV-center-containing diamond semiconductor layer being in contact with the electrode, but the NV-center-containing diamond semiconductor layer is regarded as the layer (i (n⁻) layer) having a low concentration of nitrogen, which is also an n-type impurity, and substantially acts as an insulating layer within a range of an operating voltage, thereby providing no current path between the second diamond semiconductor layer and the third diamond semiconductor layer. The structure of the diamond semiconductor device according to Example 2 is schematically illustrated in FIG. 10.

### <Current-Voltage Characteristics>

Current-voltage characteristics of the diamond semiconductor device according to Example 2 were measured by the same method as the method described in Example 1.

As a result, the same current-voltage characteristics as those of the diamond semiconductor device according to Example 1 were obtained, and the diamond semiconductor device according to Example 2 was also confirmed to exhibit a clear rectifying characteristic. That is, it was confirmed that a lateral PIN diode was properly formed.

Specifically, when a forward voltage of 5 V or more is applied, the diode is turned on, and when a voltage less than that is applied, the diode is turned off.

Further, in an ON state, electroluminescence light emission was observed.

### <Light Emission Characteristics>

Light emission characteristics of the diamond semiconductor device according to Example 2 were analyzed by the same method as the method described in Example 1.

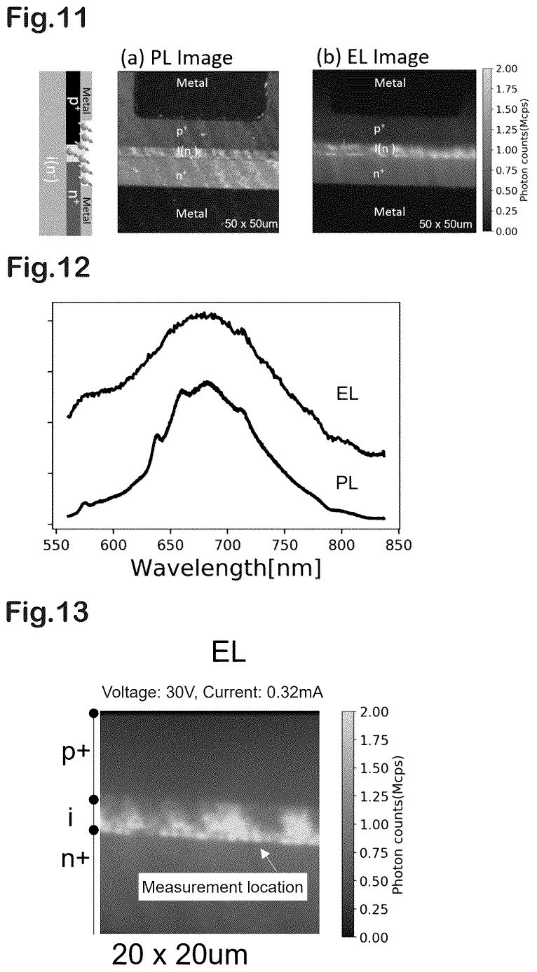

FIG. 11 shows two-dimensional mapping images of light emission of the NV-center-containing diamond semiconductor layer observed from the first diamond semiconductor layer (i (n⁻) layer) near the center of the lateral PIN diode structure. In FIG. 11, part (a) shows a photoluminescence image, and part (b) shows an electroluminescence image.

As shown in FIG. 11, bright spots were confirmed also in the electroluminescence image of the diamond semiconductor device according to Example 2 in the same manner as in that of the diamond semiconductor device according to Example 1. In addition, those bright spots were bright spots confirmed to have the same light emission pattern as in the photoluminescence image and located at the same positions as those in the photoluminescence image. Therefore, it is confirmed that electrical excitation and EL emission occur in each single one of the NV centers.

Further, FIG. 12 shows light emission spectra of photoluminescence (PL) and the electroluminescence (EL).

From the spectral shapes shown in FIG. 12, a zero-phonon line at 637 nm and a phonon sideband, both of which are typical of the NV⁻, can be confirmed, and it is confirmed that the bright spots are each light emission originating from the NV⁻.

That is, the single-photon emission from the negatively charged NV⁻ was successfully obtained also in the diamond semiconductor device according to Example 2.

### Example 3

A diamond semiconductor device according to Example 3 was manufactured in accordance with the configuration illustrated in FIG. 1. In Example 3, the NV-center-containing diamond semiconductor layer is formed by changing the method of forming the NV-center-containing diamond semiconductor layer from the ion implantation method in Example 1 to the CVD method. Further, unlike in Example 2, the NV-center-containing diamond semiconductor layer in Example 3 is formed by being embedded in the diamond semiconductor layer (i (n⁻) layer).

Specific description thereof is given below.

<First Diamond Semiconductor Layer: i (n⁻) Layer; and Formation of NV-center-containing Diamond Semiconductor Layer: CVD Method>

First, a diamond substrate (manufactured by TISNCM; type Ib substrate), which was off-cut at an off-cut angle exhibiting slight inclination and had a (111) plane as its main surface, was prepared.

When the off-angle and off-direction of the diamond substrate were measured by the X-ray diffraction method, the off-angle was 3.2° and the off-direction was a direction displaced by −5° from <−1-12>.

Subsequently, the i (n⁻)-type diamond semiconductor layer serving as the first diamond semiconductor layer and the nitrogen-doped diamond layer containing the NV centers serving as the NV-center-containing diamond semiconductor layer were continuously formed on the diamond substrate by the plasma chemical vapor deposition apparatus as follows.

First, the hydrogen gas, the methane gas and the phosphine gas that imparts the n-type conductivity were used as source gases to be respectively introduced into the plasma chemical vapor deposition apparatus with a flow rate of 996 sccm for the hydrogen gas, a flow rate of 4 sccm for the methane gas and a flow rate of 5 sccm for the hydrogen-diluted phosphine gas (phosphine concentration: 0.1% by volume), and the first diamond semiconductor layer was formed on the diamond substrate under deposition conditions for the plasma chemical vapor deposition apparatus of a plasma input power of 3,600 W, a pressure of 150 Torr and a deposition time of 5 hours.

The phosphorus concentration in the first diamond semiconductor layer measured by the SIMS analyzer was 1×10¹⁷ cm⁻³. Other impurities, hydrogen and nitrogen were below the background level of the SIMS analysis, and boron was below the detection limit.

Further, the thickness of the first diamond semiconductor layer, as measured by the SIMS analyzer, was 20 μm.

Further, the surface of the first diamond semiconductor layer was formed in a shape in which terrace surfaces and step surfaces were alternately formed in one direction in conformity with a surface shape of the diamond substrate. Further, the terrace surface had a (111) plane in conformity with the surface shape of the diamond substrate.

Specifically, the hydrogen gas, the methane gas and the nitrogen gas for forming the NV centers were used as source gases to be respectively introduced into the plasma chemical vapor deposition apparatus with a flow rate of 999 sccm for the hydrogen gas, a flow rate of 1 sccm for the methane gas and a flow rate of 0.05 sccm for the nitrogen gas, and the NV-center-containing diamond semiconductor layer was formed on the first diamond semiconductor layer under deposition conditions for the plasma chemical vapor deposition apparatus of a plasma input power of 3,500 W, a pressure of 120 Torr and a deposition time of 15 minutes.

The nitrogen concentration in the NV-center-containing diamond semiconductor layer, as measured by the SIMS analyzer, was 1×10¹⁸ cm⁻³.

Further, the thickness of the NV-center-containing diamond semiconductor layer, as measured by the SIMS analyzer, was 0.5 μm.

Subsequently, the hydrogen gas, the methane gas and the phosphine gas were again used as source gases to be respectively introduced into the plasma chemical vapor deposition apparatus with a flow rate of 996 sccm for the hydrogen gas, a flow rate of 4 sccm for the methane gas and a flow rate of 5 sccm for the hydrogen-diluted phosphine gas (phosphine concentration: 0.1% by volume), and the first diamond semiconductor layer was regrown on the NV-center-containing diamond semiconductor layer under deposition conditions for the plasma chemical vapor deposition apparatus of a plasma input power of 3,600 W, a pressure of 150 Torr and a deposition time of 30 minutes, to thereby produce a diamond semiconductor structure in which the NV-center-containing diamond semiconductor layer was formed by being embedded in the first diamond semiconductor layer in a manner that the NV-center-containing diamond semiconductor layer was sandwiched between the first diamond semiconductor layer formed earlier and the first diamond semiconductor layer formed later.

The phosphorus concentration in the first diamond semiconductor layer corresponding to the regrown portion, as measured by the SIMS analyzer, was 1×10¹⁷ cm⁻³.

Further, the thickness of the first diamond semiconductor layer corresponding to the regrown portion, as measured by the SIMS analyzer, was 1.5 μm.

Further, the surface of the first diamond semiconductor layer (regrown portion) was formed in a shape in which terrace surfaces and step surfaces were alternately formed in one direction in conformity with the surface shape of the diamond substrate. Further, the terrace surface had a (111) plane in conformity with the surface shape of the diamond substrate.

### <Second Diamond Semiconductor Layer: N⁺ Layer>

Next, the second diamond semiconductor layer was selectively grown on the first diamond semiconductor layer through use of the metal mask in the same manner as in Example 1 except that the pressure condition for film formation was changed from 75 Torr to 25 Torr.

The phosphorus concentration in the second diamond semiconductor layer, as measured by the SIMS analyzer, was 3×10²⁰ cm⁻³.

Further, the thickness of the second diamond semiconductor layer, as measured by the SIMS analyzer, was 0.18 μm.

<Third Diamond Semiconductor Layer: p⁺ Layer>

Next, the third diamond semiconductor layer was selectively grown on the first diamond semiconductor layer through use of the metal mask in the same manner as in Example 1. The boron concentration and thickness in the third diamond semiconductor layer, as measured by the SIMS analyzer, were the same as in Example 1.

### <Electrode>

Next, in the same manner as in Example 1, the electrode (stacked electrode of Au (100 nm)/Pt (30 nm)/Ti (30 nm)) was formed on each of the surfaces of the second diamond semiconductor layer and the third diamond semiconductor layer.

Through the above-mentioned steps, the diamond semiconductor device according to Example 3 was manufactured.

### <Current-Voltage Characteristics>

Current-voltage characteristics of the diamond semiconductor device according to Example 3 were measured by the same method as the method described in Example 1.

As a result, the same current-voltage characteristics as those of the diamond semiconductor device according to Example 1 were obtained, and the diamond semiconductor device according to Example 3 was also confirmed to exhibit a clear rectifying characteristic. That is, it was confirmed that a lateral PIN diode was properly formed.

Specifically, when a forward voltage of 5 V or more is applied, the diode is turned on, and when a voltage less than that is applied, the diode is turned off.

Further, in an ON state, electroluminescence light emission was observed.

### <Light Emission Characteristics>

Light emission characteristics of the diamond semiconductor device according to Example 3 were analyzed by the same method as the method described in Example 1.

FIG. 13 shows a two-dimensional mapping image of electroluminescence of the NV-center-containing diamond semiconductor layer observed from the first diamond semiconductor layer (i (n⁻) layer) near the center of the lateral PIN diode structure.

As shown in FIG. 13, the single-photon emission from the negatively charged NV⁻ was successfully obtained also in the electroluminescence image of the diamond semiconductor device according to Example 3 in the same manner as in that of each of the diamond semiconductor devices according to Examples 1 and 2.

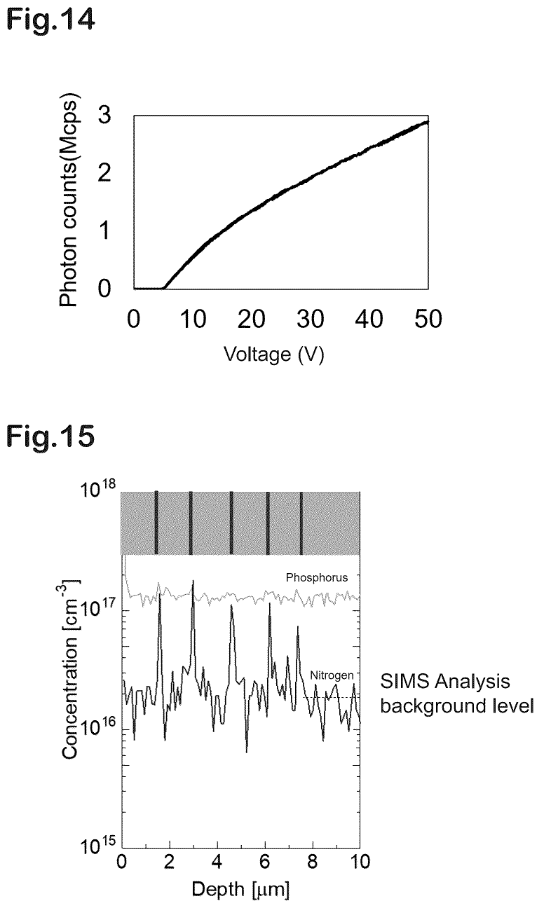

Further, FIG. 14 shows a relationship between a voltage applied to the lateral PIN diode structure in the diamond semiconductor device according to Example 3 and a light emission intensity of the electroluminescence.

As has already been described, an amount of a current flowing through the lateral PIN diode increases in accordance with application of voltage (see FIG. 7), and as shown in FIG. 14, it is understood that an electroluminescence intensity also increases as the applied voltage increases.

That is, the intensity of the EL light emission caused from the NV⁻ can be controlled by an applied voltage value (current injection amount).

### Example 4

A diamond semiconductor device according to Example 4 was manufactured in accordance with the configuration illustrated in FIG. 5. The diamond semiconductor device according to Example 4 is configured such that the number of the NV-center-containing diamond semiconductor layers formed by being embedded in the first diamond semiconductor layer in Example 3 is changed from one layer to five layers.

Specific description thereof is given below.

First, a diamond substrate (manufactured by Sumitomo Electric Industries, Ltd.; type Ib substrate), which was off-cut at an off-cut angle exhibiting slight inclination and had a (111) plane as its main surface, was prepared.

When the off-angle and off-direction of the diamond substrate were measured by the X-ray diffraction method, the off-angle was 2.3° and the off-direction was a direction displaced by +5° from <−1-12>.

Subsequently, the first diamond semiconductor layer (lowermost layer) was formed on the diamond substrate in the same manner as in Example 3 except that the flow rate of the hydrogen-diluted phosphine gas (phosphine concentration: 0.1% by volume) was changed from 5 sccm to 8 sccm and the film formation time was changed from 5 hours to 2 hours.

The phosphorus concentration in the first diamond semiconductor layer (lowermost layer), as measured by the SIMS analyzer, was 1.5×10¹⁷ cm⁻³. Other impurities, hydrogen and nitrogen were below the background level of the SIMS analysis, and boron was below the detection limit.

Further, the thickness of the first diamond semiconductor layer (lowermost layer), as measured by the SIMS analyzer, was 10 μm.

Further, the surface of the first diamond semiconductor layer (lowermost layer) was formed in a shape in which terrace surfaces and step surfaces were alternately formed in one direction in conformity with the surface shape of the diamond substrate. Further, the terrace surface had a (111) plane in conformity with the surface shape of the diamond substrate.

Subsequently, the NV-center-containing diamond semiconductor layer was formed on the first diamond semiconductor layer (lowermost layer) in the same manner as in Example 3 except that the film formation time was changed from 15 minutes to 3 minutes.

Subsequently, the first diamond semiconductor layer (regrown layer) was formed on the NV-center-containing diamond semiconductor layer in the same manner as in Example 3 except that the flow rate of the hydrogen-diluted phosphine gas (phosphine concentration: 0.1% by volume) was changed from 5 sccm to 8 sccm.

Further, growth formation of the NV-center-containing diamond semiconductor layer and the first diamond semiconductor layer (regrown layer) was alternately repeated four times in the stated order under the above-mentioned conditions, to thereby produce a structure in which a total of five NV-center-containing diamond semiconductor layers were formed by being embedded in the first diamond semiconductor layer.

The phosphorus concentration in each of the first diamond semiconductor layers corresponding to the regrown portions, as measured by the SIMS analyzer, was 1.5×10¹⁷ cm⁻³.

Further, the total thickness of the first diamond semiconductor layer including the NV-center-containing diamond semiconductor layers and the regrown portions, as measured by the SIMS analyzer, was 17 μm.

The nitrogen concentration in the NV-center-containing diamond semiconductor layers, as measured by the SIMS analyzer, was approximately 1×10¹⁷ cm−3, and the nitrogen concentration in the other regions (first diamond semiconductor layers corresponding to the regrown portions) was below the background level of the SIMS analysis.

Further, the thickness of the NV-center-containing diamond semiconductor layer, as measured by the SIMS analyzer, was 0.1 μm.

As evidence, results of SIMS analysis of a structure in which five NV-center-containing diamond semiconductor layers are embedded in the first diamond semiconductor layer are shown in FIG. 15.

<Second Diamond Semiconductor Layer: n⁺ Layer; Third Diamond Semiconductor Layer: p⁺ Layer; and Electrode>

Next, in the same manner as in Example 3, the second diamond semiconductor layer, the third diamond semiconductor layer and the electrode (stacked electrode of Au (100 nm)/Pt (30 nm)/Ti (30 nm)) were formed on a sample in which the first diamond semiconductor layer corresponding to the regrown portion and serving as the outermost layer was formed.

Through the above-mentioned steps, the diamond semiconductor device according to Example 4 was manufactured.

As indicated in this manufacturing example of the diamond semiconductor device according to Example 4, the diamond semiconductor device according to the present invention can be obtained by alternately and continuously growing the first diamond semiconductor layer and the NV-center-containing diamond semiconductor layer depending on the selection of the source gases and the like, and a plurality of the NV-center-containing diamond semiconductor layers can be formed by being embedded in the first diamond semiconductor layer.

### REFERENCE SIGNS LIST

10, 20, 30, 100 diamond semiconductor device
11, 21, 31 diamond substrate
12, 22, 32 first diamond semiconductor layer
13, 23, 33a, 33b, 33c NV-center-containing diamond semiconductor layer
14, 24, 34 second diamond semiconductor layer
15, 25, 35 third diamond semiconductor layer
16 antenna circuit

1. A diamond semiconductor device, comprising:
a first diamond semiconductor layer doped with phosphorus;
a second diamond semiconductor layer arranged on a surface of the first diamond semiconductor layer, and doped with an n-type impurity at a concentration higher than a phosphorus concentration in the first diamond semiconductor layer so as to have an n-type conductivity;
a third diamond semiconductor layer arranged on the surface of the first diamond semiconductor layer so as to be spaced apart from the second diamond semiconductor layer, and doped with a p-type impurity at a concentration higher than the phosphorus concentration in the first diamond semiconductor layer so as to have a p-type conductivity; and
an NV-center-containing diamond semiconductor layer, which has a crystal structure in which NV centers are formed, and is: embedded in the first diamond semiconductor layer so as to be opposed to the surface of the first diamond semiconductor layer at a position sandwiched between the second diamond semiconductor layer and the third diamond semiconductor layer; arranged on the surface of the first diamond semiconductor layer at the position sandwiched between the second diamond semiconductor layer and the third diamond semiconductor layer; or arranged on a back surface of the first diamond semiconductor layer so as to be opposed to the surface of the first diamond semiconductor layer at the position sandwiched between the second diamond semiconductor layer and the third diamond semiconductor layer.

2. The diamond semiconductor device according to claim 1, wherein the diamond semiconductor device is configured such that an NV axis in at least one of the NV centers is perpendicular to a path of a current caused to flow in an in-plane direction of the first diamond semiconductor layer from the third diamond semiconductor layer toward the second diamond semiconductor layer.

3. The diamond semiconductor device according to claim 1, wherein the surface of the first diamond semiconductor layer has a (111) plane.

4. The diamond semiconductor device according to claim 1, wherein the phosphorus concentration in the first diamond semiconductor layer is from 1×10¹⁵ cm⁻³ to 1×10¹⁸ cm⁻³.

5. The diamond semiconductor device according to claim 1, wherein a thickness of the first diamond semiconductor layer is from 0.1 μm to 50 μm.

6. The diamond semiconductor device according to claim 1, wherein a concentration of the NV centers in the NV-center-containing diamond semiconductor layer is 1×10¹⁹ cm⁻³ or less.

7. The diamond semiconductor device according to claim 1, wherein a value of a product of the phosphorus concentration in the first diamond semiconductor layer and a thickness of the first diamond semiconductor layer is larger than a value of a product of a concentration of the NV centers in the NV-center-containing diamond semiconductor layer and a thickness of the NV-center-containing diamond semiconductor layer.

8. The diamond semiconductor device according to claim 1, wherein a plurality of the NV-center-containing diamond semiconductor layers are arranged.

9. The diamond semiconductor device according to claim 1, wherein the NV-center-containing diamond semiconductor layer is embedded in the first diamond semiconductor layer, and an embedding depth of the NV-center-containing diamond semiconductor layer, as viewed from the surface of the first diamond semiconductor layer, is 25 μm or less.

10. The diamond semiconductor device according to claim 1, wherein a distance between the second diamond semiconductor layer and the third diamond semiconductor layer is from 0.1 μm to 50 μm.

11. The diamond semiconductor device according to claim 1, wherein the second diamond semiconductor layer exhibits hopping conduction.

12. The diamond semiconductor device according to claim 1, wherein the third diamond semiconductor layer exhibits hopping conduction.

13. The diamond semiconductor device according to claim 1, further comprising an antenna circuit of microwaves or RF waves arranged such that an NV axis in at least one of the NV centers is perpendicular to an extending direction of an antenna.
